(19) United States
(12) Patent Application Publication
(10) Pub. No.: US 2007/0046531 A1
(43) Pub. Date: Mar. 1, 2007

(54) Bluetooth satellite receiver device powered by a cigarette lighter socket

(75) Inventor: Cheng-Lu Yu, Jhubei City (TW)

Correspondence Address: BIRCH STEWART KOLASCH & BIRCH, PO BOX 747, FALLS CHURCH, VA, 22040-0747, US

(73) Assignee: HOLUX Technology Inc.

(21) Appl. No.: 11/488,612

(22) Filed: Jul. 19, 2006

(30) Foreign Application Priority Data
Aug. 26, 2005 (TW) 94214644

(51) Int. Cl. G01S 5/14; H04B 1/38; H05K 11/02; H04B 1/06

(52) U.S. Cl. 342/357.1; 455/557; 455/345

(57) ABSTRACT

The present invention discloses a Bluetooth satellite receiver device powered by a cigarette lighter socket, which comprises: a cigarette lighter plug module, inserted into a cigarette lighter socket to obtain power from a vehicle; a power supply module, electrically coupled to the cigarette lighter plug module, and supplying power to the device; a satellite receiver module, electrically coupled to the power supply module; and a Bluetooth communication module, electrically coupled to the power supply module. The satellite receiver module receives the signals from a satellite in an orbit and then decodes the signals into a latitudinal and longitudinal information and sends the latitudinal and longitudinal information to the Bluetooth communication module. The Bluetooth communication module receives the latitudinal and longitudinal information and sends it out wirelessly. The user utilizes a portable electronic device having the Bluetooth receiver function to receive the abovementioned information. The present invention provides a resident vehicle Bluetooth satellite receiver device, which implements a Bluetooth portable electronic device to receive the information from a satellite for navigation or other GIS application.

### BACKGROUND OF THE INVENTION

1. Field of the Invention

The present invention relates to a resident vehicle Bluetooth satellite receiver device, particularly to a Bluetooth satellite receiver device without a built-in battery, which may be miniaturized, embellished and continuously installed to the cigarette lighter socket of a vehicle and functions as well as a built-in device of the vehicle.

2. Description of the Related Art

GPS (global positioning system) is an important apparatus for aircrafts. Via GPS, an aircraft can find the assigned flight path in the vast sky and reach the destination safely. Recently, the automobile industry likes to adopt aviation technologies, and the vehicle GPS system has gradually become a standard apparatus of a vehicle, whereby the driver can find the path in the complicated traffic network.

With the rapid advance of wireless communication technologies, the design of the vehicle GPS products is also diversified to convenience users.

Vehicle GPS devices may be divided into the fixed type and the portable type. The fixed type vehicle GPS device, which is installed in a vehicle fixedly, often becomes an object coveted by thieves when the driver parks the vehicle outside. The portable type vehicle GPS device, which can be installed to a vehicle easily without damaging the existing interior decoration of the vehicle and can be carried about by the user conveniently, has becomes the mainstream of vehicle GPS devices. The combination of a GPS receiver and a PDA/SMART PHONE with a built-in navigation software is the most common mode of the portable vehicle GPS devices.

The PDA or SMART PHONE itself is a portable product carried about by the user everywhere originally. Now to obtain a navigation function, the user has to further carry about a GPS receiver, wired or wireless, which does really inconvenience the user.

Therefore, the present invention intends to propose a solution, wherein the existing equipment of the vehicle is used to make the GPS module function as well as a built-in one; the user neither needs to carry about the GPS receiver every time when he parks or stops over nor needs to worry about the recharging problem. Besides, receiving the information of the GPS system with a portable electronic device (such as a PDA or SMART PHONE) has been the current trend.

In view of the existing devices of a vehicle, the cigarette lighter socket is the most convenient device to provide power for a GPS receiver. Further, the Bluetooth GPS receiver may be fabricated to be as small as a vehicle cigarette lighter. Thus, the Bluetooth GPS receiver powered by cigarette lighter socket not only can be easily installed and conveniently used but also occupies no space.

### SUMMARY OF THE INVENTION

The primary objective of the present invention is to provide a Bluetooth satellite receiver device powered by a cigarette lighter socket, which has a built-in satellite receiver module and a built-in Bluetooth communication module. The user can utilize a portable electronic device to receive the signals sent out by the device of the present invention. The present invention is advantaged in that the user needn't carry about the satellite receiver device everywhere, and that the user needn't worry about the recharging problem of the battery.

Another objective of the present invention is to provide a resident vehicle Bluetooth satellite receiver device, which is not powered by a satellite navigation device but by the vehicle. Therefore, it is unnecessary to worry about whether the Bluetooth satellite receiver device will exhaust the power of the satellite navigation device (a portable electronic device). Further, if necessary, power output terminals may also be installed to the device of the present invention; thereby, the device of the present invention may recharge the abovementioned satellite navigation device or portable electronic device.

To achieve the abovementioned objectives, the present invention proposes a Bluetooth satellite receiver device powered by a cigarette lighter socket, which at least includes: a cigarette lighter plug module, inserted into a cigarette lighter socket to obtain power from a vehicle; a power supply module, electrically connected with the cigarette lighter plug module, and supplying power to the device; a satellite receiver module, electrically connected with the power supply module; and a Bluetooth communication module, electrically connected with the power supply. The satellite receiver module receives the signals from a satellite in an orbit and then decodes the signals into a latitudinal and longitudinal information and then sends the information to the Bluetooth communication module. The Bluetooth communication module receives the latitudinal and longitudinal information and sends it out wirelessly. The user can use a Bluetooth portable electronic device to receive and utilize the latitudinal and longitudinal information.

Further, the present invention provides a resident vehicle Bluetooth satellite receiver device, whereby the user can use a Bluetooth portable electronic device to receive the satellite information for navigation or GIS (Geographic Information System) application, and the user neither needs to carry about the Bluetooth satellite receiver device powered by a cigarette lighter socket nor needs to recharge the Bluetooth satellite receiver device powered by a cigarette lighter socket.

To enable the objectives, structural characteristics, and functions of the present invention to be more easily understood, the embodiments of the present invention are to be described in cooperation with the drawings below.

### BRIEF DESCRIPTION OF THE DRAWINGS

FIG. 1 is a block diagram schematically showing the architecture of the Bluetooth satellite receiver device powered by a cigarette lighter socket according to one embodiment of the present invention.

### DETAILED DESCRIPTION OF THE INVENTION

The detailed description and the preferred embodiments of the present invention are to be stated in cooperation with the attached drawings below.

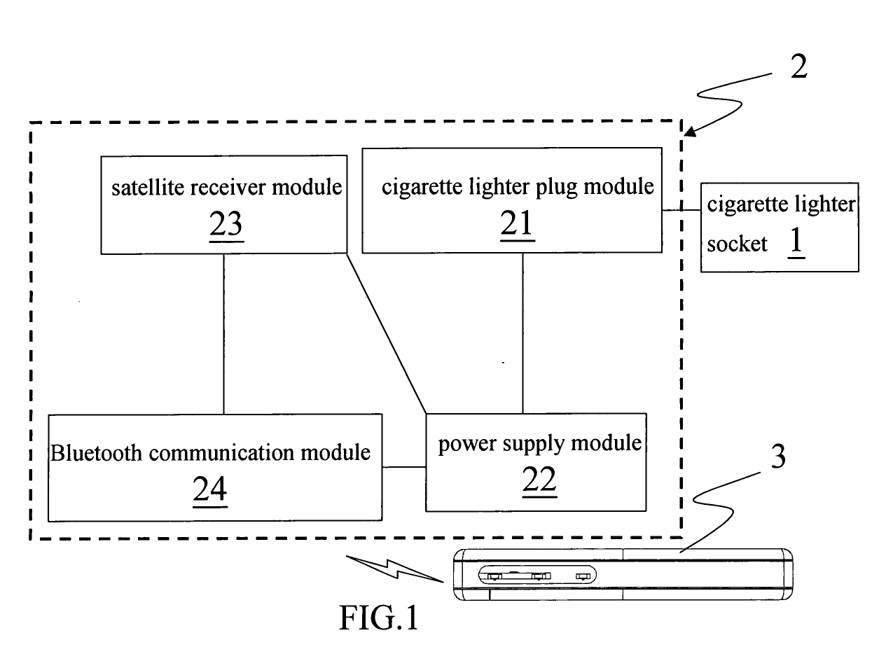

Refer to FIG. 1 a block diagram showing one embodiment of the present invention. As shown in FIG. 1, the Bluetooth satellite receiver device powered by a cigarette lighter socket 2 of the present invention at least includes: a cigarette lighter plug module 21, inserted into a cigarette lighter socket 1 to obtain power from a vehicle; a power supply module 22, electrically connected with the cigarette lighter plug module 21, and supplying power to the device 2; a satellite receiver module 23, electrically connected with the power supply module 22; and a Bluetooth communication module 24, electrically connected with the power supply module 22. The satellite receiver module 23 receives the signals from a satellite in an orbit and decodes the signals into a latitudinal and longitudinal information and sends the information to the Bluetooth communication module 24. The Bluetooth communication module 24 receives the latitudinal and longitudinal information and sends it out wirelessly. The user may use a Bluetooth portable electronic device 3 to receive and utilize the satellite signals.

The cigarette lighter plug module 21 is electrically connected with a vehicle via the cigarette lighter socket 1 and supplies power for the device 2 of the present invention. The power supply module 22 transforms the 12V or 24V power, which is received by the cigarette lighter plug module 21 via the cigarette lighter socket 1, into the power needed by the satellite receiver module 23, the Bluetooth communication module 24 and the other modules of the device 2 of the present invention. Besides, the power supply module 22 can also stabilize the current supply.

The satellite receiver module 23 may be in the form of a satellite signal-receiving chip embedded into the Bluetooth satellite receiver device powered by a cigarette lighter socket 2 or in the form of a satellite receiver module constructed in the Bluetooth satellite receiver device powered by a cigarette lighter socket 2.

The Bluetooth communication module 24 may be in the form of a Bluetooth chip embedded into the Bluetooth satellite receiver device powered by a cigarette lighter socket 2 or in the form of a Bluetooth communication module constructed in the Bluetooth satellite receiver device powered by a cigarette lighter socket 2. The Bluetooth communication module 24 can receive and transmit signals wirelessly. The satellite receiver module 23 receives signals from a satellite in an orbit via an antenna and decodes the signals into latitudinal and longitudinal information and sends the latitudinal and longitudinal information to the Bluetooth communication module 24. The Bluetooth communication module 24 sends the latitudinal and longitudinal information out wirelessly via the antenna thereof. The antenna of the satellite receiver module 23/the Bluetooth communication module 24 may be a built-in antenna or an external antenna.

The user can use a portable electronic device 3, which also has a Bluetooth communication module, to receive the satellite navigation information sent out by the Bluetooth communication module 24. Any portable electronic device (such as a personal digital assistant or a mobile phone) having a Bluetooth communication module may be used as the portable electronic device 3 to receive the satellite navigation information. When the user utilizes the portable electronic device 3 in navigation or GIS application, he neither needs to carry about the Bluetooth satellite receiver device powered by a cigarette lighter socket nor needs to recharge the Bluetooth satellite receiver device powered by a cigarette lighter socket.

The Bluetooth satellite receiver device powered by a cigarette lighter socket of the present invention may further have power output terminals. If necessary, the portable electronic device 3 can be recharged by the Bluetooth satellite receiver device powered by a cigarette lighter socket via the power output terminals.

In the Bluetooth satellite receiver device powered by a cigarette lighter socket 2 of the present invention, the satellite receiver module 23 and the Bluetooth communication module 24 are built in the vehicle, and the user needn't worry about the problems of power consumption and battery recharging. The user does not need to purchase extra portable electronic device but can use the existing Bluetooth portable electronic device 3 to receive the satellite information. Therefore, the present invention outperforms the conventional satellite navigation device obviously.

Those described above are only the preferred embodiments to clarify the present invention. However, it is not intended to limit the scope of the present invention, and any equivalent modification and variation according to the spirit of the present invention is to be also included within the scope of the claims of the present invention.

What is claimed is:

1. A Bluetooth satellite receiver device powered by a cigarette lighter socket, comprising:
a cigarette lighter plug module, inserted into a cigarette lighter socket to obtain power;
a power supply module, electrically connected with said cigarette lighter plug module, and supplying power to said device;
a satellite receiver module, electrically connected with said power supply module; and
a Bluetooth communication module, electrically connected with said power supply module,
wherein said satellite receiver module receives signals from a satellite in an orbit and decodes the signals into a latitudinal and longitudinal information and sends said latitudinal and longitudinal information to said Bluetooth communication module, and said Bluetooth communication module sends said latitudinal and longitudinal information out wirelessly.

2. The Bluetooth satellite receiver device powered by a cigarette lighter socket according to claim 1, wherein said satellite receiver module is in the form of a chip embedded inside said Bluetooth satellite receiver device.

3. The Bluetooth satellite receiver device powered by a cigarette lighter socket according to claim 1, wherein said satellite receiver module is in the form of a module constructed inside said Bluetooth satellite receiver device.

4. The Bluetooth satellite receiver device powered by a cigarette lighter socket according to claim 1, wherein said Bluetooth communication module is in the form of a chip embedded inside said Bluetooth satellite receiver device.

5. The Bluetooth satellite receiver device powered by a cigarette lighter socket according to claim 1, wherein said Bluetooth communication module is in the form of a module constructed inside said Bluetooth satellite receiver device.

6. The Bluetooth satellite receiver device powered by a cigarette lighter socket according to claim 1, wherein said satellite receiver module further comprises a built-in antenna.

7. The Bluetooth satellite receiver device powered by a cigarette lighter socket according to claim 1, wherein said satellite receiver module further comprises an external antenna.

8. The Bluetooth satellite receiver device powered by a cigarette lighter socket according to claim 1, wherein said Bluetooth communication module further comprises a built-in antenna.

9. The Bluetooth satellite receiver device powered by a cigarette lighter socket according to claim 1, wherein said Bluetooth communication module further comprises an external antenna.

10. The Bluetooth satellite receiver device powered by a cigarette lighter socket according to claim 1, wherein the wireless signals sent out by said Bluetooth communication module is received by a portable electronic device with a Bluetooth communication module.

11. The Bluetooth satellite receiver device powered by a cigarette lighter socket according to claim 10, wherein said portable electronic device may be a wearing-type electronic device, a personal digital assistant, a mobile phone, or another handheld electronic device.

12. The Bluetooth satellite receiver device powered by a cigarette lighter socket according to claim 10, further comprising power output terminals used to recharge said portable electronic device.
